(19) United States
(12) Patent Application Publication
(10) Pub. No.: US 2022/0157707 A1
(43) Pub. Date: May 19, 2022

(54) THIN SEMICONDUCTOR PACKAGE AND MANUFACTURING METHOD THEREOF

(71) Applicant: Panjit International Inc., Kaohsiung City (TW)

(72) Inventors: Chung-Hsiung Ho, Kaohsiung City (TW); Chi-Hsueh Li, Tainan City (TW); Wei-Ming Hong, Kaohsiung City (TW)

(21) Appl. No.: 17/099,979

(22) Filed: Nov. 17, 2020

(51) Int. Cl. H01L 23/498; H01L 21/768; H01L 21/463

(52) U.S. Cl. CPC H01L 23/49861; H01L 21/463; H01L 21/76873; H01L 23/49872

(57) ABSTRACT

A thin semiconductor package includes a die paddle and multiple lead fingers made of a metal substrate. A die paddle electroplating layer and a lead finger electroplating layer are formed on the surface of the die paddle and surfaces of the lead fingers, respectively. A die is provided on the die paddle electroplating layer and is electrically connected to the lead finger electroplating layer. The die paddle, the die and the lead fingers are encapsulated by a molding compound. The lower surfaces of the die paddle and the lead fingers are exposed on the bottom surface of the molding compound. The die paddles and the lead fingers are formed by etching the metal substrate instead without using a lead frame.

### BACKGROUND OF THE INVENTION

### 1. Field of the Invention

The present invention relates to semiconductor packaging technology, in particular to a package without a lead frame.

### 2. Description of the Prior Arts

Most conventional semiconductor packages use lead frames as substrates. Referring to FIG. 6, a lead frame 50 mainly includes a die paddle 51 and multiple lead fingers 52. The die paddle 51 is provided with a die. The multiple lead fingers 52 are electrically connected to the die for transmitting signals to an external circuit board. However, the surface of the lead frame 50 may not be flat enough, and there may be a problem of poor electrical connection in subsequent die bonding process and wire bonding process. In addition, as a single-piece lead frame 50 is composed of multiple units connected by connecting ribs 53, cross sections of the connecting ribs 53 will be exposed from the sides of the individual packages after the cutting process, which causes copper exposure.

FIGS. 7A to 7E show a conventional packaging process of a diode. Referring to FIG. 7A, an upper surface of a lead frame 60 is partially etched to form a die paddle 61 and multiple inner lead fingers 62. The adjacent inner leads 62 are separated by an upper notch 63 formed by etching.

In FIG. 7B, a die 64 is provided on the die paddle 61, and the die 64 is electrically connected to the inner lead fingers 62 through a wire bonding process.

In FIG. 7C, a molding compound 65 is formed through a molding process. The molding compound can cover the die 64 and the inner lead fingers 62 and also fill the upper notch 63 on the upper surface of the lead frame 60.

In FIG. 7D, a lower surface of the lead frame 60 is etched to form multiple outer lead fingers 66 through the etching process. The multiple outer lead fingers 66 correspond to the multiple inner lead fingers 62 respectively. Multiple lower notches 67 are formed on the lower surface of the lead frame 60 by etching. The adjacent outer lead fingers 66 are separated from each other by the lower notches 67. Further, portions of the molding compound 65 are exposed from the lower notch 67.

In FIG. 7E, an insulating layer 68 is printed on part of the surface of the outer lead fingers 66 to insulate the outer lead fingers 66.

However, in the semiconductor manufacturing process of FIGS. 7A to 7E, it is necessary to precisely control the two etching processes of the lead frame 60, such as the etching rate and the etching position. In addition, it also needs the insulating layer 68 to avoid short circuits, which increases the cost and difficulty of the packaging process.

### SUMMARY OF THE INVENTION

In view of the above problems, the present invention provides a thin semiconductor package and manufacturing method thereof.

A thin semiconductor package comprises:

a die paddle made of a metal substrate and having an upper surface and a lower surface;

a die paddle electroplating layer formed on the upper surface of the die paddle, wherein, a first undercut is formed around an edge between the upper surface of the die paddle and the die paddle electroplating layer;

a die mounted on the upper surface of the die paddle;

multiple lead fingers made of the metal substrate and arranged adjacent to the die paddle, wherein each lead finger has an upper surface and a lower surface;

a lead finger electroplating layer formed on the upper surface of each lead finger and electrically connected to the die, wherein a second undercut is formed around an edge between the upper surface of the lead finger and the lead finger electroplating layer;

a molding compound covering the die paddle, the die and the multiple lead fingers;

wherein, the lower surface of the die paddle and the lower surfaces of the lead fingers are exposed from the bottom surface of the molding compound and are coplanar with the bottom surface of the molding compound.

A method of manufacturing a thin semiconductor package comprises:

electroplating a patterned electroplating layer on the upper surface of a metal substrate, wherein the patterned electroplating layer includes a die paddle electroplating layer and a lead finger electroplating layer;

etching the upper surface of the metal substrate to form etching portions by using the patterned electroplating layer as a mask, wherein an undercut is formed at the bonding edge of the upper surface of the metal substrate and the patterned electroplating layer;

attaching a die on the die paddle electroplating layer and electrically connecting the die to the lead finger electroplating layer;

providing a molding compound on the upper surface of the metal substrate to cover the electroplating layer and the die and fill the etching portions;

grinding the top surface of the molding compound to a predetermined thickness;

performing a planarization process on the lower surface of the metal substrate until the molding compound is exposed to form the die paddles and lead fingers, wherein the lower surface of each die paddle and the lower surfaces of the lead fingers are separated by the molding compound;

sawing the metal substrate to obtain multiple independent semiconductor packages.

In the present invention, die paddles and lead fingers are formed by processing the upper and lower surfaces of a metal substrate, so there is no need to use a traditional lead frame, thereby avoiding the problems resulted from the traditional lead frame, such as uneven surface of the lead frame, and copper exposure from the cross section of the connecting ribs. Further, there is no need to provide a taping on the bottom surface of the lead frame.

### BRIEF DESCRIPTION OF THE DRAWINGS

FIGS. 1A to 1G are schematic diagrams of a manufacturing process of a package of the present invention.

FIG. 2 is a perspective schematic diagram of a diode metal substrate formed by the method of the present invention.

FIG. 3A is a perspective schematic diagram of the metal substrate of FIG. 2 after die bonding and wire bonding.

FIG. 3B is a top view of the metal substrate of FIG. 2 after die bonding and wire bonding.

FIG. 4 is a perspective schematic diagram of the metal substrate of FIGS. 3A and 3B after encapsulating.

FIG. 5A is a top perspective schematic view of a diode package.

FIG. 5B is a bottom perspective schematic view of the diode package.

FIG. 5C is a schematic view of the diode package viewed from X direction in FIG. 5A.

FIG. 5D is a schematic view of the diode package viewed from Y direction in FIG. 5A.

FIG. 6 is a perspective schematic diagram of a conventional lead frame.

FIGS. 7A to 7E are schematic diagrams of the manufacturing process of conventional semiconductor packages using a lead frame.

### DETAILED DESCRIPTION OF THE PREFERRED EMBODIMENTS

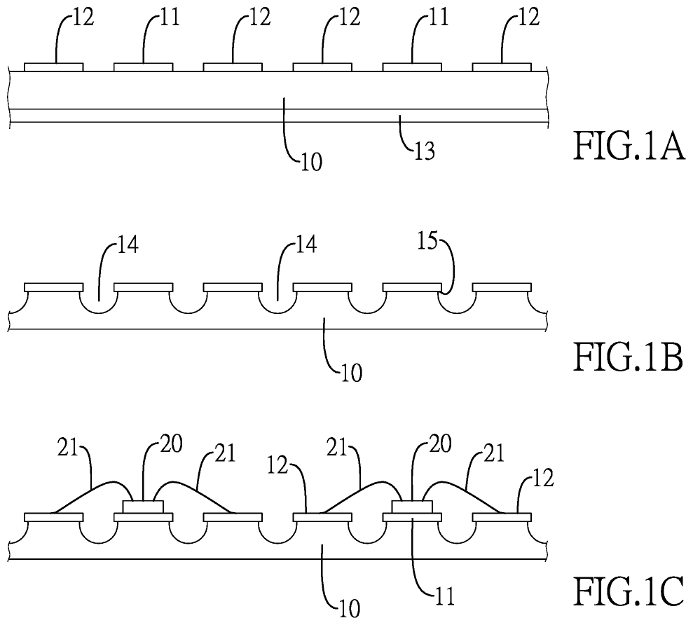

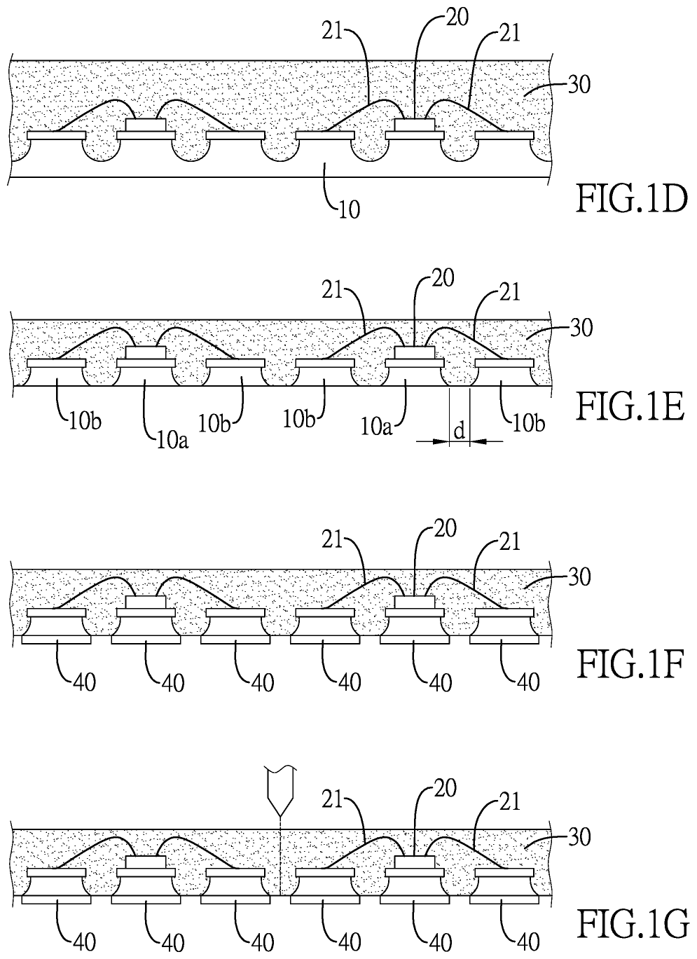

The present invention provides a thin semiconductor package and a method of manufacturing the thin semiconductor package. To illustrate the present invention, FIG. 1A to FIG. 1G show the manufacturing processes of the semiconductor package, wherein the size and position of the components in the figures are for illustration purpose only.

Referring to FIG. 1A, the present invention provides a metal substrate 10 that can be a copper substrate instead of a common lead frame. A patterned electroplating layer is formed on an upper surface of the metal substrate 10 by an electroplating process. The electroplating layer includes a die paddle electroplating layer 11 and a lead finger electroplating layer 12 distinct from each other according to their functions. The pattern and position of the die paddle electroplating layer 11 and the lead finger electroplating layer 12 can be designed according to actual requirements of the production. Further, a protective layer 13 is attached on the lower surface of the metal substrate 10. The protective layer 13 can be composed of dry film, photo resist (PR) and other materials, which can prevent etching agents from etching the lower surface of the metal substrate 10 during etching process.

Referring to FIG. 1B, the upper surface of the metal substrate 10 is etched by wet etching process. The electroplating layer can be used as a hard mask during the etching process. The etching agents can etch down the metal substrate 10 that are not covered by the electroplating layer to form concave etching portions 14. The depth of the etching portion 14 is about half the thickness of the metal substrate 10. The metal substrate 10 around the etching portion 14 has a curved surface. Further, an undercut 15 is formed around an edge between the electroplating layer and the upper surface of the metal substrate 10. After the etching process, the protective layer 13 is removed to form the metal substrate 10 as shown in FIG. 1B.

Referring to FIG. 1C, a die 20 is provided on the die paddle electroplating layer through the die bonding/wire bonding processes. The die 20 is electrically connected to the respective lead finger electroplating layer 12 by bonding wires 21.

Referring to FIG. 1D, after the die bonding/wire bonding processes, the metal substrate 10 is placed in a mold to perform a molding process. A molding compound 30 can cover the upper surface of the metal substrate 10, the die 20 and the wires 21, and fill the etching portions 14. As the undercut 15 is formed at the edge between the electroplating layer and the upper surface of the metal substrate 10, the molding compound 30 can form a flange at the undercut 15 to strengthen the bonding between the molding compound 30 and the metal substrate 10.

Referring to FIG. 1E, the upper surface of the molding compound 30 is ground to reduce the thickness of the package. The grinding thickness can be varied according to actual product requirements. Specifically, for products requiring high thickness, the molding compound 30 is less ground; on the contrary, for products requiring low thickness, the molding compound 30 is more ground. Further, a planarization process is performed on the lower surface of the metal substrate 10. In an embodiment, the planarization process is performed by etching the metal substrate 10 to expose the molding compound 30. After being etched, the metal substrate 10 below the die paddle electroplating layer 11 forms a die paddle 10a, and the metal substrate 10 below the lead finger electroplating layer 12 forms multiple lead fingers 10b. The die paddle 10a and the lead fingers 10b are insulated from each other by the molding compound 30 to avoid short circuit. In order to make the bottom surface of the semiconductor package more even, a grinding process can be performed on the bottom surface of the die paddle 10a, the multiple lead fingers 10b and the molding compound 30.

In another embodiment, the planarization process is performed by grinding the metal substrate 10 to expose the molding compound 30. After being ground, the metal substrate 10 below the die paddle electroplating layer 11 forms a die paddle 10a, and the metal substrate 10 below the lead finger electroplating layer 12 forms multiple lead fingers 10b.

In the present invention, a distance d between adjacent lead fingers 10b can be determined by controlling the planarization process, such as controlling etching time, grinding time and so on. For example, the distance d is greater as the lower surface of the metal substrate 10 is more etched/ground. In a preferred embodiment, the distance d is greater than 100 μm. Referring to FIG. 1F, a protective layer 40 is further formed on the bottom surface of each die paddle 10a and each lead finger 10b. The protective layer 40 can be formed by a method such as electroless nickel immersion gold (ENIG), etc.

Referring to FIG. 1G, after the protective layer 40 is formed, a sawing tool is used to perform an insulation process to obtain a plurality of independent semiconductor packages.

A diode package is taken as an example to describe the present invention. For understanding, reference symbols of the diode package are the same as the reference symbols denoted in FIGS. 1A to 1G. The shape and relative position of the die paddle and lead fingers of the diode package may be different from those in FIGS. 1A to 1G, but the processing steps are the same.

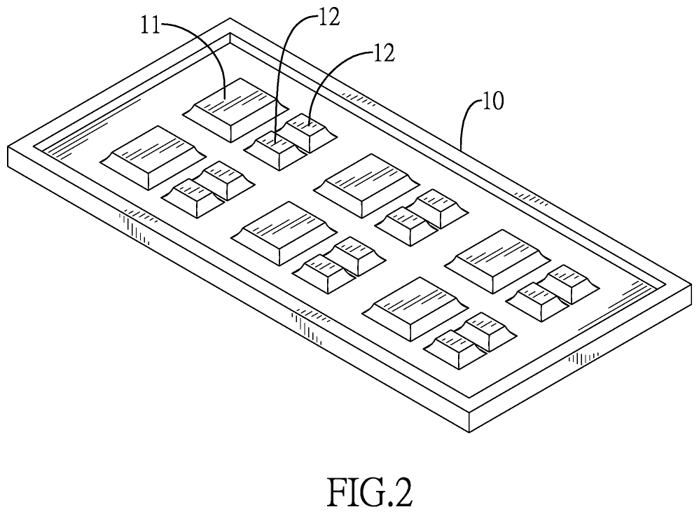

Referring to FIG. 2, after the upper surface of the metal substrate 10 is etched, it can be seen that multiple die paddle electroplating layers 11 and lead finger electroplating layers 12 are formed, wherein two parallel lead finger electroplating layers 12 are provided on one side of each die paddle electroplating layer 11.

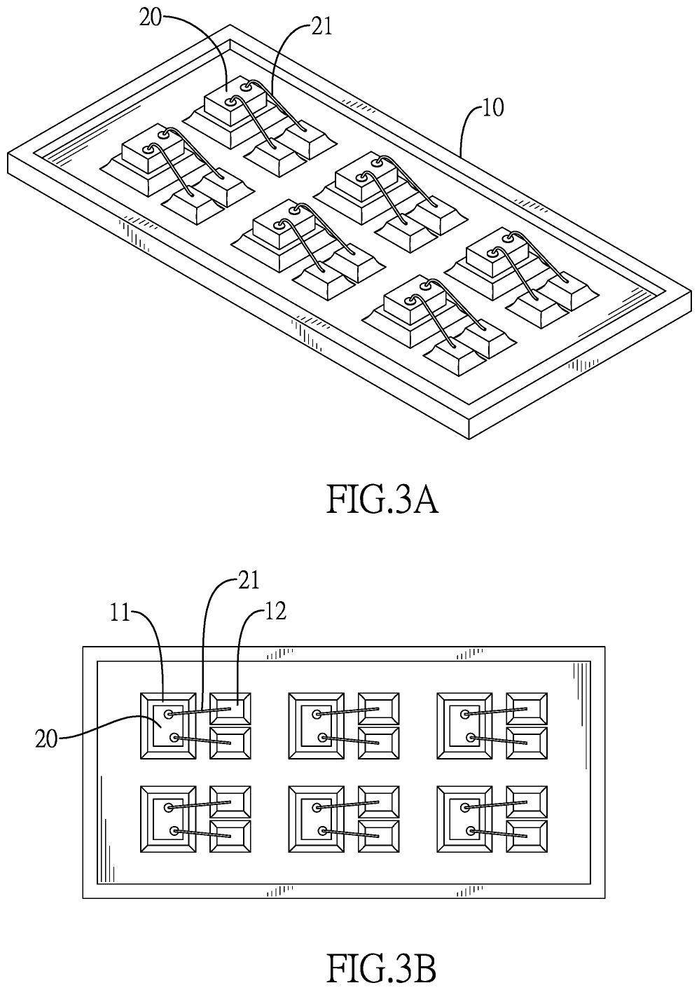

Referring to FIG. 3A and FIG. 3B, die bonding process and wire bonding process are performed on the metal substrate 10 in FIG. 2. The die 20 of the diode is bonded on each die paddle electroplating layer 11, and the die 20 is connected to the respective lead finger electroplating layer 12 through the wires 21.

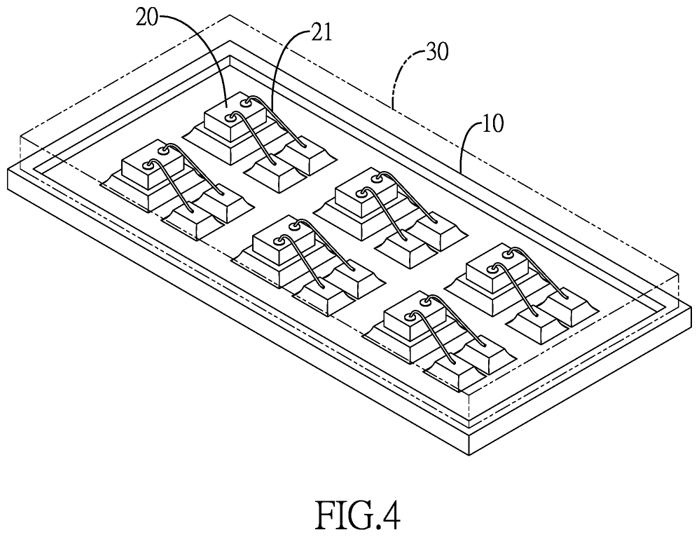

In FIG. 4, the molding process is performed on the metal substrate 10 to form the molding compound 30 that encapsulates the die 20 and wire 21.

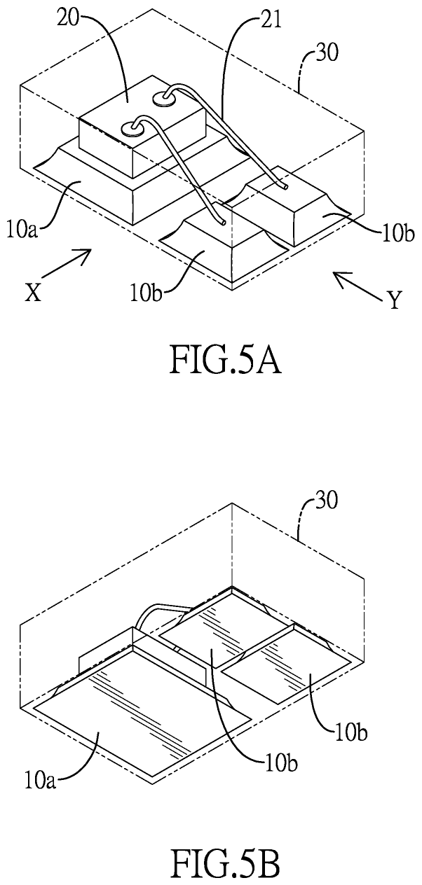

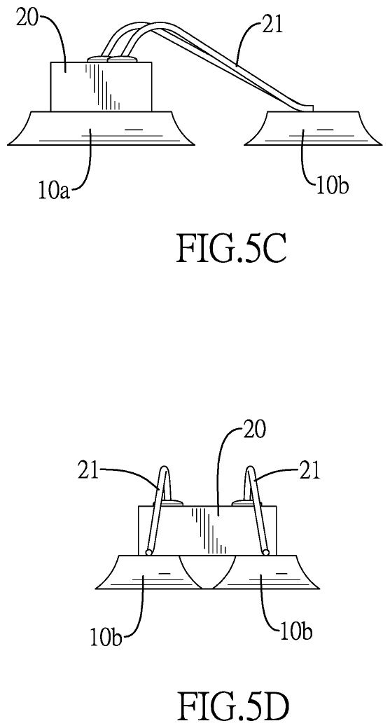

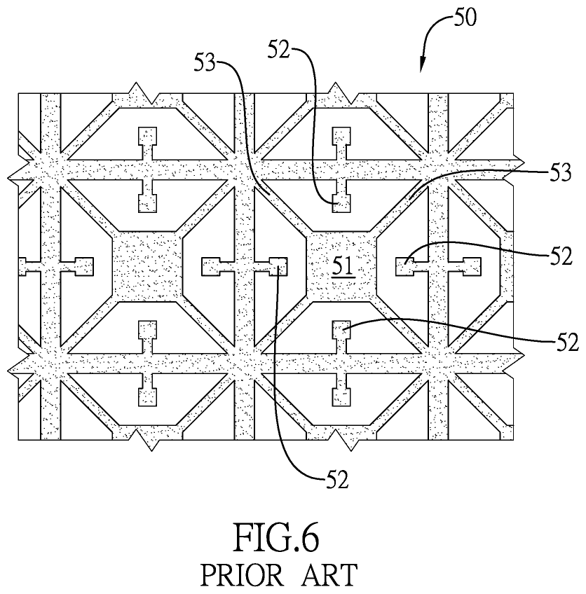

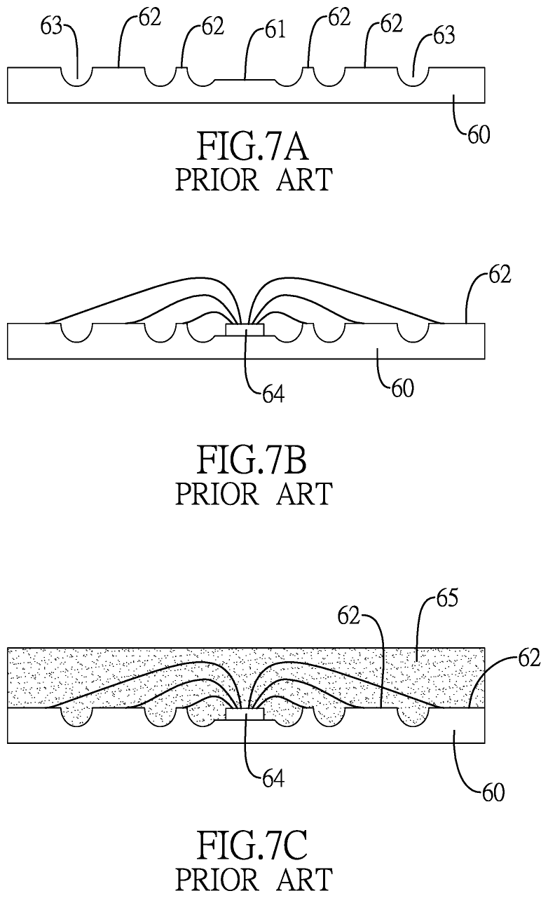

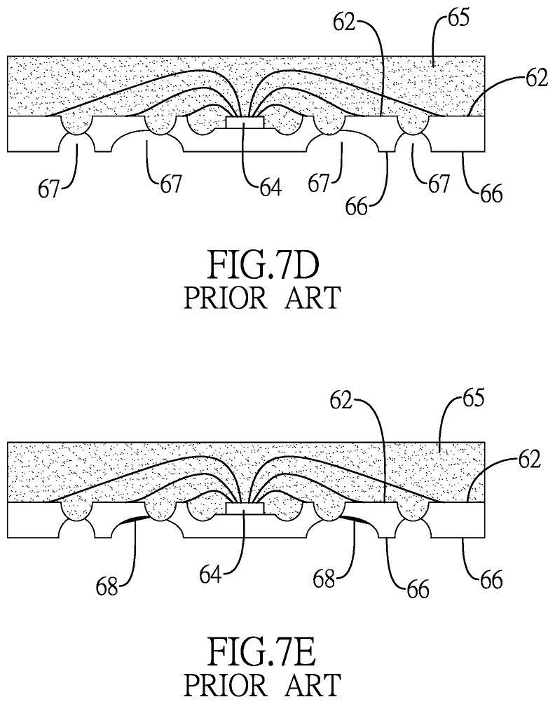

FIGS. 5A to 5D show a single diode package after the cutting process. After the lower surface of the metal substrate 10 is etched, the die paddle 10a and the two lead fingers 10b separated from each other are formed. The shapes, sizes and relative positions of die paddle 10a and the two lead fingers 10b can be varied by the actual specifications of the production. For example, in this embodiment, the lower surfaces of the die pad 10a and each lead 10b are larger than their upper surfaces, and then they are trapezoidal when viewed from the side.

Based on the above, the packaging process of the present invention has the following advantages:

1. As the metal substrate 10 is processed to form the die paddles and lead fingers, there is no need to use the lead frame, which can avoid the problems of uneven surface of lead frame and copper exposure in the cross section of the connecting ribs. Further, there is no need to attach a taping to the bottom surface of the lead frame.

2. Packages of different thickness can be obtained with the same molding mold. In the prior art, different packages need respective different molds to form the required thickness of the molding compound 30. However, in the present invention, the molding compound 30 is formed by a single mold, and is further ground to the required thickness according to the actual requirement of production. So there is no need to use multiple different molds.

3. The shape and position of the die paddles and lead fingers of the package can be made based on the actual requirement of production, and the distance between adjacent lead fingers can be precisely controlled through the etching process.

What is claimed is:

1. A thin semiconductor package comprising:
a die paddle made of a metal substrate and having an upper surface and a lower surface;
a die paddle electroplating layer formed on the upper surface of the die paddle, wherein, a first undercut is formed around an edge between the upper surface of the die paddle and the die paddle electroplating layer;
a die mounted on the upper surface of the die paddle;
multiple lead fingers made of the metal substrate and arranged adjacent to the die paddle, wherein each lead finger has an upper surface and a lower surface;
a lead finger electroplating layer formed on the upper surface of each lead finger and electrically connected to the die, wherein a second undercut is formed around an edge between the upper surface of the lead finger and the lead finger electroplating layer;
a molding compound covering the die paddle, the die and the multiple lead fingers;
wherein, the lower surface of the die paddle and the lower surfaces of the lead fingers are exposed from a bottom surface of the molding compound and are coplanar with the bottom surface of the molding compound.

2. The thin semiconductor package as claimed in claim 1, wherein the die paddle and each lead finger have a curved side surface.

3. The thin semiconductor package as claimed in claim 1, wherein the die paddle and each lead finger have the same height.

4. The thin semiconductor package as claimed in claim 1, wherein the upper surface of the die paddle is smaller than the lower surface of the die paddle, and the upper surfaces of the lead fingers are smaller than the lower surfaces of the lead fingers.

5. The thin semiconductor package as claimed in claim 1, wherein a protective layer is formed on the lower surface of the die paddle.

6. The thin semiconductor package as claimed in claim 1, wherein the die paddle electroplating layer and the lead finger electroplating layer are nickel gold layers.

7. A method of manufacturing a thin semiconductor package, comprising:
electroplating a patterned electroplating layer on an upper surface of a metal substrate, wherein the patterned electroplating layer includes a die paddle electroplating layer and a lead finger electroplating layer;
etching the upper surface of the metal substrate to form etching portions by using the patterned electroplating layer as a mask, wherein an undercut is formed around an edge of the upper surface of the metal substrate and the patterned electroplating layer;
attaching a die on the die paddle electroplating layer and electrically connecting the die to the lead electroplating layer;
providing a molding compound on the upper surface of the metal substrate to cover the patterned electroplating layer and the die and fill the etching portions;
grinding a top surface of the molding compound to a predetermined thickness;
performing a planarization process on the lower surface of the metal substrate until the molding compound is exposed to form the die paddles and lead fingers, wherein the lower surface of each die paddle and the lower surfaces of the lead fingers are separated by the molding compound;
sawing the metal substrate to obtain multiple independent semiconductor packages.

8. The method as claimed in claim 7, further including:
forming a protective layer on the lower surface of each die paddle and the lower surface of each lead finger.

9. The method as claimed in claim 7, wherein each of the etching portions has a curved surface.

10. The method as claimed in claim 7, wherein the upper surface of the die paddle is smaller than the lower surface of the die paddle, and the upper surfaces of the lead fingers are smaller than the lower surfaces of the lead fingers.
